(19) United States
(12) Patent Application Publication
(10) Pub. No.: US 2025/0085323 A1
(43) Pub. Date: Mar. 13, 2025

(54) ANTENNA BEAM ESTIMATION METHOD AND APPARATUS USING BEAM INTENSITY DETECTION SHEET WITH PATTERNED COUPLING LINES

(71) Applicant: Korea Electronics Technology Institute, Seongnam-si (KR)

(72) Inventors: Seok Yeon HONG, Suwon-si (KR); Se Hwan CHOI, Seongnam-si (KR); Seung Goo NAM, Suwon-si (KR)

(73) Assignee: Korea Electronics Technology Institute, Seongnam-si (KR)

(21) Appl. No.: 18/519,288

(22) Filed: Nov. 27, 2023

(30) Foreign Application Priority Data
Sep. 11, 2023 (KR) 10-2023-0120089

(51) Int. Cl. G01R 29/08

(52) U.S. Cl. CPC G01R 29/08

(57) ABSTRACT

There is provided an antenna beam detection and monitoring apparatus which uses a beam intensity detection sheet with patterned coupling lines. The antenna beam detection apparatus according to an embodiment includes: a sheet which is disposed on an upper end of a beam radiation surface of an antenna and has a plurality of coupling lines formed therein to allow beams radiated from the antenna to be coupled thereto; and a plurality of detectors configured to measure intensities of beams coupled to the coupling lines, respectively, by using the beams radiated from the antenna. Accordingly, it is possible to monitor performance of an antenna in real time with a small-sized device and a low cost even when the antenna is operating.

### CROSS-REFERENCE TO RELATED APPLICATION(S) AND CLAIM OF PRIORITY

This application is based on and claims priority under 35 U.S.C. § 119 to Korean Patent Application No. 10-2023-0120089, filed on Sep. 11, 2023, in the Korean Intellectual Property Office, the disclosure of which is herein incorporated by reference in its entirety.

### BACKGROUND

### Field

The disclosure relates to a wireless communication technology, and more particularly, to a method for monitoring by estimating performance in real time while an antenna for wireless communication is operating.

### Description of Related Art

An array antenna may achieve beam steering by adjusting a phase, but an antenna installed in a device may have difficulty in checking whether beams are tilted in a correct direction while being operated. That is, an antenna may only be tested by an antenna in package (AiP) technology before it is released and it may be difficult to continuously check an error occurring during operation after the antenna is released.

AiP test devices which are used for a test before an antenna is released are illustrated in FIGS. 1 and 2. FIG. 1 illustrates an AiP test socket which is capable of testing under a near field condition. The AiP test socket of FIG. 1 may have a limitation such that it is only possible to measure performance in a boresight direction.

In order to test an antenna for various directions, a device capable of conducting an AiP test under a far field condition, as suggested in FIG. 2, should be used. However, this device has a problem of a large volume and a high cost.

### SUMMARY

The disclosure has been developed in order to solve the above-described problems, and an object of the disclosure is to provide an antenna beam estimation method and apparatus which uses a beam intensity detection sheet with patterned coupling lines, as a solution for monitoring performance of an antenna in real time with a small sized-device and at a low cost even when the antenna is operating.

According to an embodiment of the disclosure to achieve the above-described object, an antenna monitoring apparatus may include: a sheet in which a plurality of coupling lines are formed to allow beams radiated from an antenna to be coupled thereto; a plurality of detectors configured to measure intensities of beams coupled to the coupling lines, respectively, by using the beams radiated from the antenna; and an analyzer configured to analyze performance of the antenna, based on the intensities of the beams measured by the detectors.

The coupling lines may be arranged at regular intervals.

The antenna monitoring apparatus may include: first coupling lines of a first direction; and second coupling lines of a second direction which is perpendicular to the first direction.

The first coupling lines may be formed in a first layer of the sheet, and the second coupling lines may be formed in a second layer of the sheet which is different from the first line.

The coupling lines may transmit beams in an operating frequency band of the antenna.

The coupling lines may be formed as metal patterns, and the coupling lines may have a thickness, a spacing, and an inter-layer distance adjusted to have a band pass filter characteristic in the operating frequency band of the antenna.

The analyzer may estimate a directionality of the antenna, based on the measured intensities of beams.

The detectors may measure intensities of beams coupled to the coupling lines, respectively, while the antenna is operating.

The analyzer may estimate the directionality of the antenna before the antenna is released or in real time.

According to another aspect of the disclosure, there is provided an antenna monitoring method including: allowing beams radiated from an antenna to be coupled to a plurality of coupling lines formed in a sheet; measuring intensities of the coupled beams; and analyzing performance of the antenna, based on the measured intensities of beams.

According to still another aspect of the disclosure, there is provided an antenna beam detection apparatus comprising: a sheet in which a plurality of coupling lines are formed to allow beams radiated from an antenna to be coupled thereto; and a plurality of detectors configured to measure intensities of beams coupled to the coupling lines, respectively, by using the beams radiated from the antenna.

According to embodiments of the disclosure as described above, antenna beams may be estimated and monitored by using a beam intensity detection sheet with patterned coupling lines, so that abnormality of an antenna may be rapidly detected and quick measures may be taken, and performance of an antenna may be optimally maintained and a downtime of a system may be minimized.

According to embodiments of the disclosure, the beam intensity detection sheet may be applied to all systems using antennas, and may be applied to a pre-test of an antenna before the antenna is released. In this connection, a size and a cost of a test device may be minimized.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating a related-art AiP test socket;

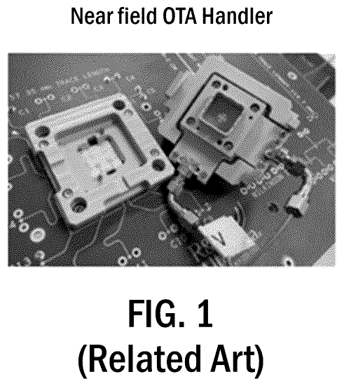

FIG. 2 is a view illustrating an AiP test device;

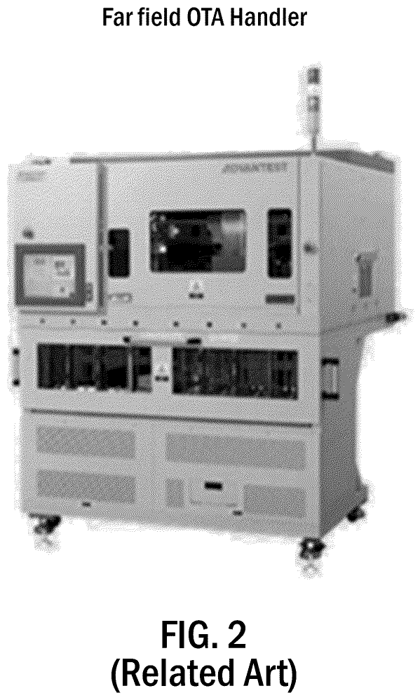

FIG. 3 is a view illustrating an example of an array antenna;

FIG. 4 is a view illustrating an antenna beam detection sheet according to an embodiment of the disclosure;

FIG. 5 is a view illustrating a unit structure of the antenna beam detection sheet shown in FIG. 4;

FIGS. 6A and 6B are views illustrating transmission loss test results of antenna beam detection sheets;

FIG. 7 is a view provided to explain a power detector of the antenna beam detection sheet;

FIGS. 8A and 8B are views provided to explain a method for estimating a directionality of an array antenna;

FIG. 9 is a top view of an antenna beam detection sheet according to another embodiment of the disclosure;

FIG. 10 is a side view of the antenna beam detection sheet according to another embodiment of the disclosure;

FIG. 11 is a view illustrating a unit structure of the antennae beam detection sheet according to an embodiment of the disclosure;

FIG. 12 is a view illustrating an overall layout of the antennae beam detection sheet according to an embodiment of the disclosure; and

FIG. 13 is an enlarged view of a portion of the power detector of FIG. 12.

### DETAILED DESCRIPTION

Hereinafter, the disclosure will be described in more detail with reference to the accompanying drawings.

Embodiments of the disclosure provide a method for estimating beams for an operating antenna in real time. A sheet with patterned coupling lines may be disposed on an upper portion of a radiation surface of an antenna to detect intensities of beams radiated from the antenna and to analyze/monitor performance of the antenna based on the result of detecting.

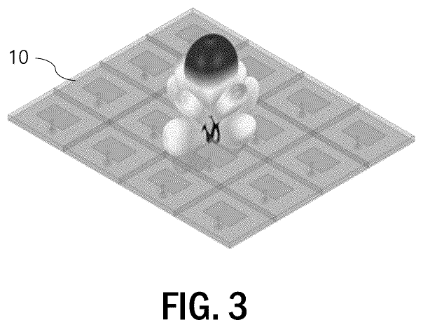

FIG. 3 illustrates an array antenna 10 which is to be analyzed and monitored for performance according to an embodiment of the disclosure. The array antenna 10 illustrated is capable of achieving beam steering by adjusting a feeding phase.

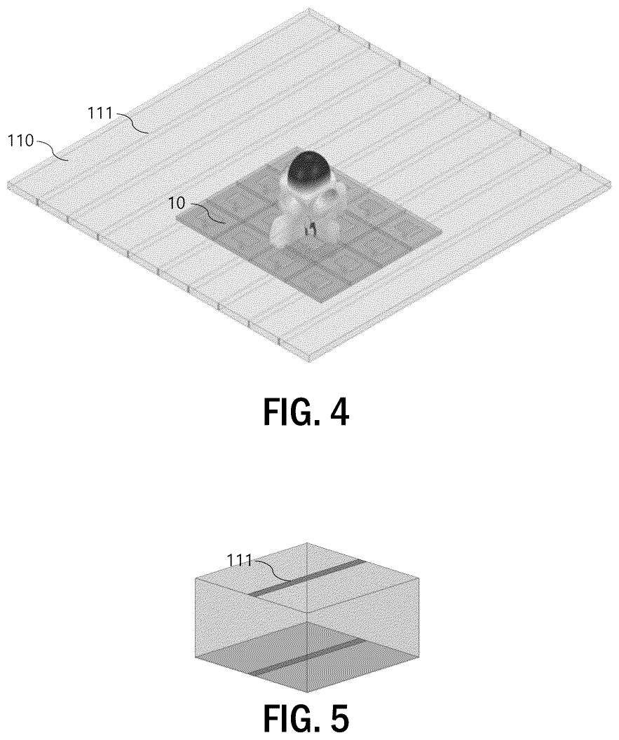

FIG. 4 illustrates that an antenna beam detection sheet 110 according to an embodiment is disposed on an upper portion of the array antenna 10 proposed in FIG. 3. As shown in FIG. 4, the antenna beam detection sheet 110 according to an embodiment may be disposed on an upper portion of a beam radiation surface of the array antenna 10.

The antenna beam detection sheet 110 according to an embodiment may have a plurality of coupling lines 111 formed therein to allow beams radiated from the array antenna 10 to be coupled thereto. As shown in the drawings, the coupling lines 111 may be arranged in parallel at regular intervals.

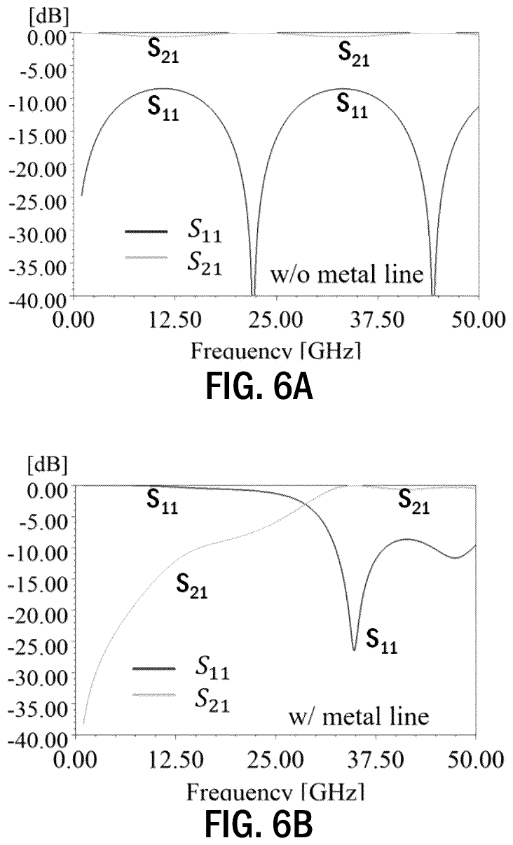

FIG. 5 schematically illustrates a unit structure of the antenna beam detection sheet 110 according to an embodiment. As shown in the drawings, the coupling lines 111 may be formed in the sheet as metal patterns, and may be designed by applying a frequency selective surface (FSS) technique so as not to influence performance of the array antenna 10 and to show characteristics of a band pass filter in a frequency band in which the array antenna 10 is operating. Specifically, a frequency transmission characteristic of the antenna beam detection sheet 110 may be adjusted by adjusting a thickness of a metal pattern for forming the coupling lines 111, a spacing (a vertical distance), and an inter-layer distance (vertical distance).

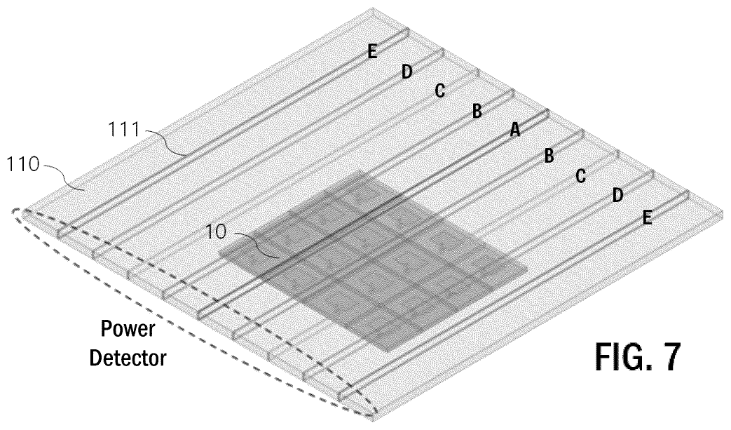

To this end, the antenna beam detection sheet 110 may enable beams to be transmitted in an operating frequency band of the array antenna 10. FIG. 6A shows result of measuring beams on an upper portion of a sheet without coupling lines 111 when the sheet is disposed on an upper portion of the array antenna 10, and FIG. 6B shows result of measuring beams on an upper portion of the antenna beam detection sheet 110 with the coupling lines 111 being formed therein when the antennae beam detection sheet 110 is disposed on an upper portion of the array antenna 10. As shown in the drawings, a FSS technique may be applied to the antennae beam detection sheet 110 so that a lower transmission loss is guaranteed in a specific frequency band.

This shows that the antenna beam detection sheet 110 has a low transmission loss in an operating frequency band of the array antenna 10, that is, a gain in an operating frequency band of the array antenna 10 does not almost change even when the antenna beam detection sheet 110 is disposed on an upper portion of the antenna. As described above, the antenna beam detection sheet 110 may be designed not to distort an operation of the array antenna 10.

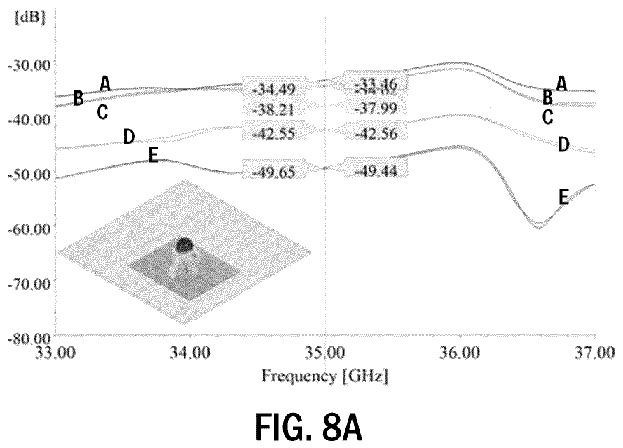

Meanwhile, as shown in FIG. 7, power detectors may be connected to ends of the coupling lines 111 of the antenna beam detection sheet 110 to measure intensities of beams coupled to the coupling lines 111 by using beams radiated from the array antenna 10.

Intensities of beams in the coupling lines may be transformed into voltages by the power detectors, and may be delivered to an antenna beam analyzer (not shown). The antenna beam analyzer monitors a bean intensity and a beam directionality of the array antenna 10 by comparing intensities of beams measured from the coupling lines 111 by the power detectors.

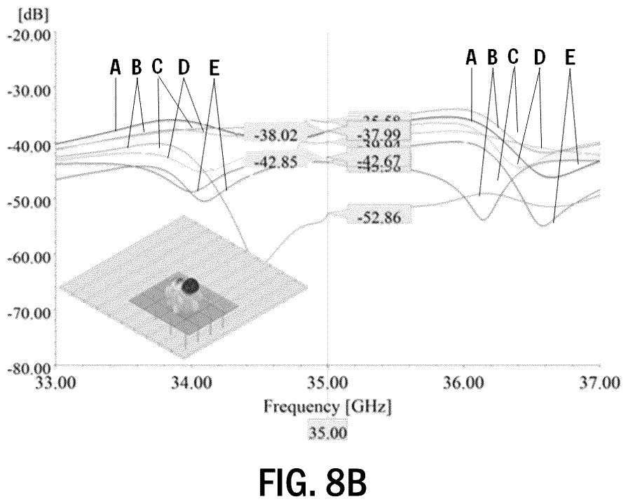

For easy explanation, FIG. 7 illustrates the coupling lines of the antenna beam detection sheet 110 with different colors, and FIGS. 8A and 8B illustrate results of measuring from the coupling lines 111 with corresponding charactors.

FIG. 8A shows result of measuring when the array antenna 10 radiates beams in a boresight direction. It may be identified that the highest beam intensity is measured from a coupling line (red) disposed in the middle of the sheet. This shows that radiation beams of the array antenna 10 are exactly formed in the boresight direction.

On the other hand, FIG. 8B shows result of measuring when beams are radiated from the array antenna 10 while being tilted to the right. In this case, it may be identified that the highest beam intensity is measured from a coupling line (yellow) positioned on the right side. This shows that radiation beams from the array antenna 10 are tilted to the right.

The results of FIGS. 8A and 8B show that intensities of beams coupled to the coupling lines 111 change according to intensities and directions of beams radiated from the array antenna 10, and imply that it is possible to monitor intensities and directions of radiation beams in real time through intensities of beams coupled to the coupling lines. Based on the result of monitoring beams from the antenna, performance of the array antenna 10 may be optimized, and abnormality may be rapidly detected and appropriate measures may be taken.

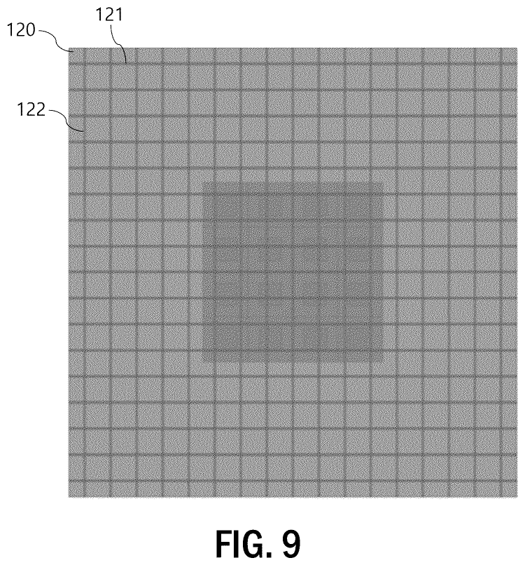

FIG. 9 illustrates an antenna beam detection sheet 120 according to another embodiment of the disclosure. There is a difference from the embodiment shown in FIG. 4 in that coupling lines 121, 122 are formed in the antenna beam detection sheet 120 in a grid pattern.

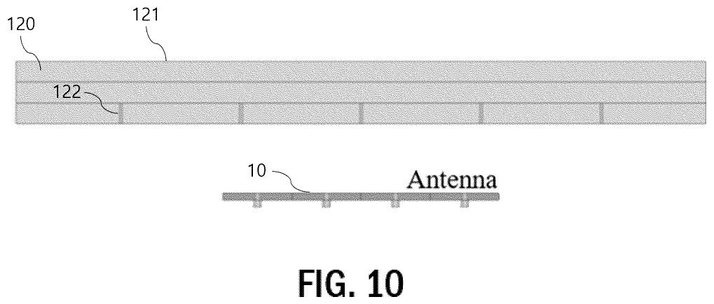

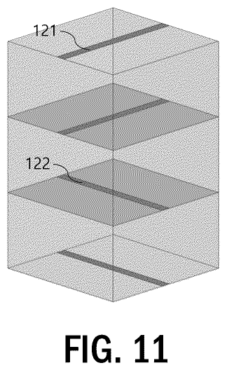

The coupling lines 121 and the coupling lines 122 may be formed in directions perpendicular to each other, and may be formed in different layers not to conduct electricity to each other, as shown in FIG. 10. FIG. 11 schematically illustrates a unit structure of the antenna beam detection sheet 120 according to an embodiment of the disclosure.

In FIG. 4, one-dimensional measurement of beam intensities is performed by the antenna beam detection sheet 110, whereas two-dimensional measurement of beam intensities is performed by the antenna beam detection sheet 120 according to an embodiment, so that intensities and directions of beams may be estimated more specifically.

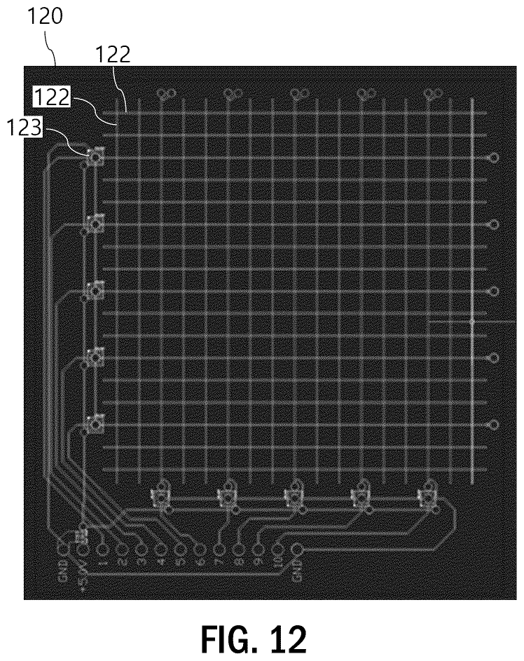

FIG. 12 illustrates an overall layout of the antenna beam detection sheet 120 shown in FIGS. 9 and 10. As shown in FIG. 12, the antenna beam detection sheet 120 may include coupling lines 121, 122 and power detectors 123 to detect beam intensities.

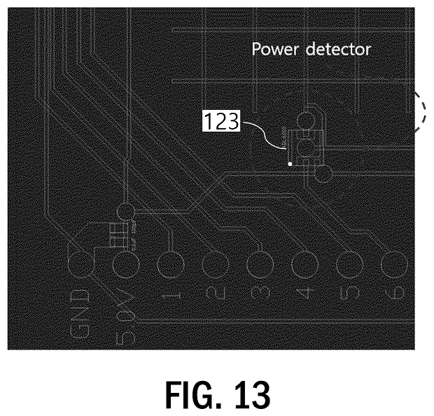

As shown in an enlarged view of FIG. 13, the coupling lines 121, 122 may be connected to the power detectors 123 as inputs, and outputs thereof represent voltage values according to beam intensities. Voltage values may be transmitted to an antenna beam analyzer (not shown), and may be used for estimating intensities and directions of beams radiated from the array antenna 10.

Up to now, the method and apparatus for monitoring by estimating antenna beams by using the antenna beam detection sheet 110, 120 with the coupling lines formed therein has been described with reference to preferred embodiments.

The antenna beam detection sheet 110, 120 may be implemented inside an upper case of the array antenna 10, or may be implemented in a lower end of the upper case. This may be an optional mater in implementing an antenna.

A distance between the antenna beam detection sheet 110, 120 and the array antenna 10 may be defined according to a standard and specifications of an antenna, and as the distance increases, an antenna beam detection sheet 110, 120 of a larger size may be required.

An antenna beam estimation system including an antenna beam detection sheet according to an embodiment of the disclosure, and an antenna beam analyzer may monitor an operational state of an antenna continuously in the middle of operating the antenna, which surpasses a related-art method of testing once before a product is released like an AiP test socket.

In addition, an antenna beam detection sheet and an antenna beam analysis device according to an embodiment of the disclosure may be applied to an AiP test before an antenna is released.

A related-art AiP test socket which uses near field may measure only performance of beams in a boresight direction, whereas the method and apparatus according to an embodiment of the disclosure may identify a phase error through beam scanning even under a near field condition when the method and apparatus are applied to an AiP test. That is, the disclosure proposes a new methodology which can measure a phase error with a related-art AiP test socket, which tests through a near field.

Furthermore, the method and apparatus according to an embodiment of the disclosure may be applied to a radio detection and ranging (RADAR). The antenna beam detection sheet according to an embodiment of the disclosure may be applied to a radome or a cover for protecting an antenna to continuously monitor the presence/absence of a breakdown of a RADAR and malfunction.

In addition, while preferred embodiments of the present disclosure have been illustrated and described, the present disclosure is not limited to the above-described specific embodiments. Various changes can be made by a person skilled in the at without departing from the scope of the present disclosure claimed in claims, and also, changed embodiments should not be understood as being separate from the technical idea or prospect of the present disclosure.

What is claimed is:

1. An antenna monitoring apparatus comprising:
a sheet in which a plurality of coupling lines are formed to allow beams radiated from an antenna to be coupled thereto;
a plurality of detectors configured to measure intensities of beams coupled to the coupling lines, respectively, by using the beams radiated from the antenna; and
an analyzer configured to analyze performance of the antenna, based on the intensities of the beams measured by the detectors.

2. The antenna monitoring apparatus of claim 1, wherein the coupling lines are arranged at regular intervals.

3. The antenna monitoring apparatus of claim 2, comprising:
first coupling lines of a first direction; and
second coupling lines of a second direction which is perpendicular to the first direction.

4. The antenna monitoring apparatus of claim 3, wherein the first coupling lines are formed in a first layer of the sheet, and
wherein the second coupling lines are formed in a second layer of the sheet which is different from the first line.

5. The antenna monitoring apparatus of claim 4, wherein the coupling lines are configured to transmit beams in an operating frequency band of the antenna.

6. The antenna monitoring apparatus of claim 5, wherein the coupling lines are formed as metal patterns, and
wherein the coupling lines have a thickness, a spacing, and an inter-layer distance adjusted to have a band pass filter characteristic in the operating frequency band of the antenna.

7. The antenna monitoring apparatus of claim 1, wherein the analyzer is configured to estimate a directionality of the antenna, based on the measured intensities of beams.

8. The antenna monitoring apparatus of claim 7, wherein the detectors are configured to measure intensities of beams coupled to the coupling lines, respectively, while the antenna is operating.

9. The antenna monitoring apparatus of claim 8, wherein the analyzer is configured to estimate the directionality of the antenna before the antenna is released or in real time.

10. An antenna monitoring method comprising:
allowing beams radiated from an antenna to be coupled to a plurality of coupling lines formed in a sheet;
measuring intensities of the coupled beams; and
analyzing performance of the antenna, based on the measured intensities of beams.

11. An antenna beam detection apparatus comprising:
a sheet in which a plurality of coupling lines are formed to allow beams radiated from an antenna to be coupled thereto; and
a plurality of detectors configured to measure intensities of beams coupled to the coupling lines, respectively, by using the beams radiated from the antenna.
